(19) United States
(12) Patent Application Publication
(10) Pub. No.: US 2025/0380408 A1
(43) Pub. Date: Dec. 11, 2025

(54) INTEGRATED CIRCUIT DEVICE WITH THREE-DIMENSIONAL INVERTED FLASH MEMORY STRUCTURE

(71) Applicant: Taiwan Semiconductor Manufacturing Company, Ltd., Hsinchu (TW)

(72) Inventors: Georgios Vellianitis, Heverlee (BE); Marcus Johannes Henricus Van Dal, Linden (BE); Gerben Doornbos, Leuven (BE)

(21) Appl. No.: 18/736,971

(22) Filed: Jun. 7, 2024

(51) Int. Cl. H10B 41/27; H01L 23/528

(52) U.S. Cl. CPC H10B 41/27; H01L 23/5283

(57) ABSTRACT

Some embodiments relate to an integrated circuit (IC) device that includes a conductive layer; a dielectric structure disposed over the conductive layer; a first conductive structure disposed within the dielectric structure and separated from the conductive layer; a semiconductor structure disposed within the dielectric structure and extending vertically from the conductive layer to the first conductive structure; a first dielectric element disposed within the dielectric structure and extending vertically from the conductive layer alongside the semiconductor structure; a conductive element disposed within the dielectric structure between and separated from the conductive layer and the first conductive structure, and extending laterally from the first dielectric element; a second conductive structure disposed within the dielectric structure and extending vertically from near a surface of the conductive element opposite the conductive layer; and a second dielectric element disposed within the dielectric structure and at least partially surrounding the second conductive structure.

### BACKGROUND

At its inception, flash memory was a welcome innovation in memory technology due to its non-volatile nature, its storage density, its ability to be erased in blocks (as opposed to the entire integrated circuit (IC) device), and its capacity to be written and read at the page or individual cell level. Over the years, significant development efforts have been focused on fabrication process enhancements resulting in enhanced storage density, operating speed, device yield, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of some embodiments of a three-dimensional (3D) inverted flash memory structure, according to the present disclosure.

FIG. 2A illustrates a cross-sectional view of some embodiments of an integrated circuit (IC) device including a single-transistor 3D inverted flash memory structure, according to the present disclosure.

FIG. 2B illustrates a cross-sectional view of some embodiments of an IC device including a multiple-transistor 3D inverted flash memory structure, according to the present disclosure.

FIGS. 3A through 3T illustrate cross-sectional views of some embodiments of an IC device including a single-transistor 3D inverted flash memory structure at multiple stages of fabrication, according to the present disclosure.

FIGS. 4A through 4E illustrate cross-sectional views of some embodiments of an IC device including a multiple-transistor 3D inverted flash memory structure at multiple stages of fabrication, according to the present disclosure.

FIG. 5 illustrates a methodology of forming some embodiments of the IC device of the single-transistor 3D inverted flash memory structure of FIGS. 3A through 3T and the multiple-transistor 3D inverted flash memory structure of FIGS. 4A through 4E, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a first flash memory integrated circuit (IC) structure, which may form a floating gate metal-oxide-semiconductor field-effect transistor (MOSFET) serving as a memory cell, a floating gate is isolated between a control gate and a semiconductor channel region by a block oxide and a tunnel oxide, respectively. In operation, charge may be stored in the floating gate by way of the channel and the tunnel oxide in the presence of a programming voltage, resulting in a programmed cell having a first threshold voltage. Oppositely, such charge may be released from the floating gate by way of the channel and the tunnel oxide in the presence of an erasing voltage, resulting in an erased cell with a second threshold voltage (e.g., less than the first threshold voltage). Consequently, reading of the cell may be performed using a read voltage between the first and second threshold voltages, thereby producing a voltage that indicates whether the cell is in the programmed or erased state.

In some other flash memory IC devices, an “inverted” flash memory IC structure may be used, in which the tunnel oxide is positioned between the floating gate and the control gate, instead of between the floating gate and the channel, as described above. A potential benefit of the inverted flash structure may be that some parameters, such as the “memory window” of the cell (e.g., the difference between the first and second threshold voltages) may be tuned by way of the size of the control gate, the tunnel oxide, and so on.

In some cases, the storage density of a flash memory device may be increased by employing an IC fabrication process that vertically stacks multiple memory cells of the first flash memory IC structure within a single IC die to form a three-dimensional (3D) flash memory IC structure. However, a similar 3D memory cell architecture employing an inverted flash memory IC structure that provides the parameter tuning features mentioned above has proven somewhat difficult.

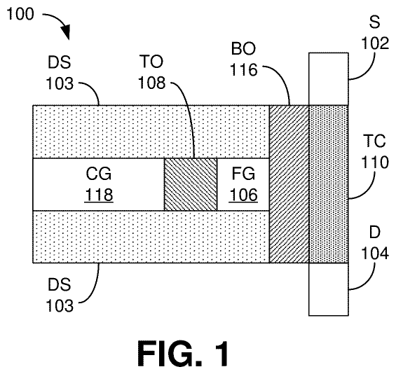

To address these issues, the present disclosure provides some embodiments of a 3D inverted flash memory IC device that may include a laterally-extending floating gate structure. FIG. 1 illustrates a schematic view of some embodiments of a three-dimensional (3D) inverted flash memory structure 100, according to the present disclosure. Unlike a vertically-stacked inverted flash memory, in which multiple layers of a structure may be vertically stacked atop each other, 3D inverted flash memory structure 100 generally may include a plurality of layers that are situated laterally to each other. As depicted in FIG. 1, 3D inverted flash memory structure 100 may include, in order from right to left, a semiconductor structure 110 serving as a transistor channel (TC), a first dielectric element 116 serving as a block oxide (BO), a conductive element 106 serving as a floating gate (FG), a second dielectric element 108 serving as a tunnel oxide (TO), and a conductive structure 118 serving as a control gate (CG). In some embodiments, conductive structures 102 and 104 (e.g., serving as transistor source and drain) may be located at opposing ends of semiconductor structure 110. While FIG. 1 depicts the source positioned over semiconductor structure 110 and the drain positioned under semiconductor structure 110, the positions of the source and drain may be reversed. Surrounding at least a portion of inverted flash memory structure 100 may be a dielectric structure (DS) 103.

In some embodiments, some of the structures or elements of a 3D inverted flash memory structure, as described below, may be oriented vertically relative to each other. For example, a control gate structure may extend vertically toward the floating gate structure, and may be isolated from the floating gate structure by a layer of tunnel dielectric material substantially surrounding the control gate structure. Such a structure may be employed in both a single-transistor inverted flash memory structure that employs a single floating gate and associated control gate and associated tunnel dielectric, as well as a multiple-transistor inverted flash memory structure that includes two to or more floating gate structures, each being associated with a separate control gate and tunnel dielectric.

When such structures, as described in greater detail in some embodiments below, are used, a relatively large memory window may be provided, and tuning of various other parameters associated with the flash memory structure may be possible by way of adjusting the size of the control and floating gates, the thickness of the tunnel dielectric, and other structural characteristics of the flash memory structure. Further, such benefits may be possible while enabling the vertical stacking of multiple transistors employed in the 3D flash memory structures.

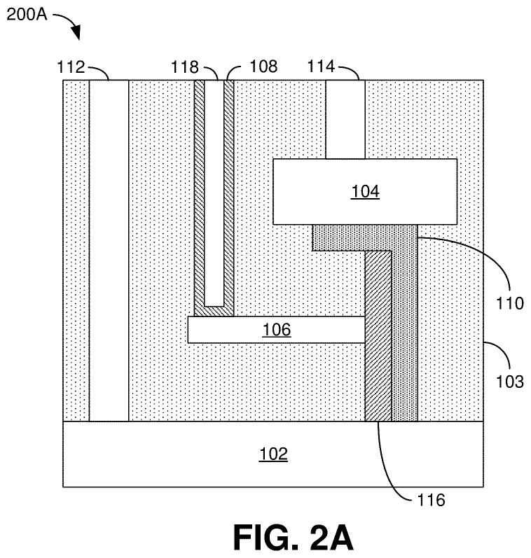

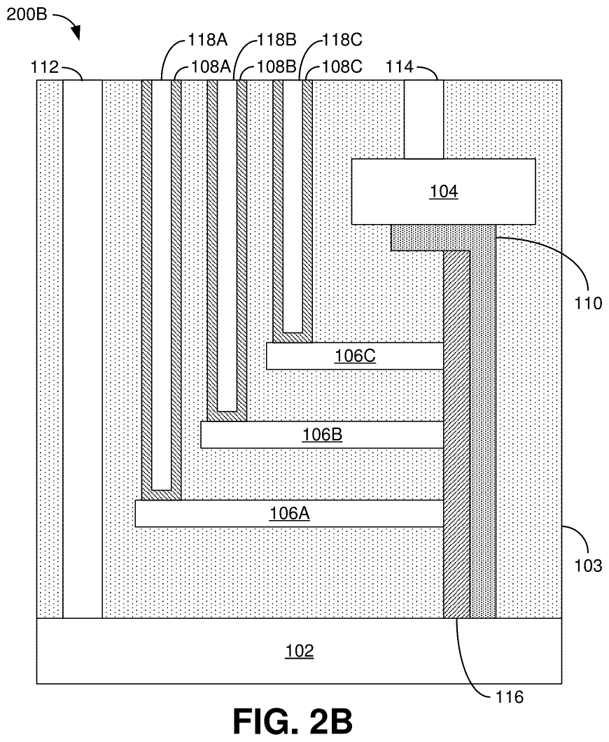

FIG. 2A illustrates a cross-sectional view of some embodiments of an integrated circuit (IC) device 200A including a single-transistor 3D inverted flash memory structure, according to the present disclosure. As shown, a conductive layer 102 may serve as a substrate, or as a layer supported by a substrate, for the remainder of the inverted flash memory cell structure, as described below. In some embodiments, conductive layer 102 may operation as a first source-drain structure (e.g., a source) for the single-transistor inverted flash memory structure.

Disposed over conductive layer 102 may be a dielectric structure 103 in which the remaining elements of the inverted flash memory structure are located. More specifically, a first conductive structure 104 (e.g., a second source-drain region, such as a drain) may be disposed over conductive layer 102. Coupling conductive layer 102 and first conductive structure 104 may be a semiconductor structure 110 that extends substantially vertically from conductive layer 102 to first conductive structure 104. Further, in some embodiments, semiconductor structure 110 may extend laterally along a lower surface of first conductive structure 104. In some embodiments, semiconductor structure 110 may operate as a transistor channel between a source (e.g., conductive layer 102) and a drain (e.g., first conductive structure 104) of a transistor.

In some embodiments, within dielectric structure 103, a first dielectric element 116 may extend vertically from conductive layer 102 alongside the vertically extending portion of semiconductor structure 110 to the laterally extending portion of semiconductor structure 110. Consequently, in some embodiments, semiconductor structure 110 may isolate first dielectric element 116 from first conductive structure 104. In some embodiments, first dielectric element 116 may service as a block dielectric (e.g., a block oxide) for the flash memory transistor structure.

Further, in some embodiments, a conductive element 106 disposed within dielectric structure 103 may extend laterally from first dielectric element 116, and may serve as a floating gate for the flash memory transistor structure. Consequently, in some embodiments, first dielectric element 116 (e.g., the block oxide) may isolate conductive element 106 (e.g., the floating gate), at a first end of conductive element 106, from semiconductor structure 110 (e.g., the transistor channel).

In some embodiments, near a second end of conductive element 106, a second dielectric element 108 may be disposed within dielectric structure 103 and substantially surround a vertically extending second conductive structure 118, thus isolating second conductive structure 118 from conductive element 106. In some embodiments, second dielectric element 108 may operate as a tunnel dielectric (e.g., a tunnel oxide), while second conductive structure 118 may serve as a control gate for the flash memory transistor structure. Further, in some embodiments, second conductive structure 118 may not use a separate contact structure to connect to other electronic circuitry (e.g., for reading, programming, and/or erasing the flash memory cell).

In some embodiments, as also depicted in FIG. 2A, are a first conductive contact structure 112 disposed within the dielectric structure 103 and extending vertically from conductive layer 102, as well as a second conductive contact structure 114 extending vertically from first conductive structure 104. Accordingly, in some embodiments, first conductive contact structure 112 and second conductive contact structure 114 may provide electrical connectivity for the source and drain of the flash memory transistor to other circuitry (e.g., control circuitry for programming, erasing, and/or reading of the flash memory structure).

In some embodiments, given the structure of IC device 200A, adjustment of various structural aspects thereof (e.g., the thickness of second dielectric element 108, a surface area of second dielectric element 108 in contact with conductive element 106, a width of second conductive structure 118, and so on) may affect the size of the memory window and other parameters of interest (e.g., the speed of programming, erasing, and reading operations, the amount of charge stored in the floating gate when programmed, the amount of time the stored charge persists in the floating gate, and the like) with respect to flash memory operation.

FIG. 2B illustrates a cross-sectional view of some embodiments of an IC device 200B including a multiple-transistor 3D inverted flash memory structure, according to the present disclosure. In some embodiments, several of the same components discussed above in conjunction with IC device 200A of FIG. 2A (e.g., conductive layer 102, dielectric structure 103, first conductive structure 104, semiconductor structure 110, first dielectric element 116, first conductive contact structure 112, and second conductive contact structure 114) are depicted in IC device 200B of FIG. 2B. However, instead of a single conductive element 106, a single second dielectric element 108, and a single second conductive structure 118, as depicted in FIG. 2A, FIG. 2B includes multiple (e.g., three) groups of such elements.

More specifically, each of three conductive elements 106A, 106B, and 106C, at a first end thereof, extend laterally from the same single first dielectric element 116, and are isolated from conductive layer 102, first conductive structure 104, and each other. Further, in some embodiments, each of the three conductive elements 106A, 106B, and 106C contacts, near a second end opposite the first end, a corresponding second dielectric element 108A, 108B, and 108C. Additionally, in some embodiments, each second dielectric element 108A, 108B, and 108C substantially surrounds a corresponding second conductive structure 118A, 118B, and 118C. Further, each set of elements (e.g., a first set including conductive element 106A, second dielectric element 108A, and second conductive structure 118A; a second set including conductive element 106B, second dielectric element 108B, and second conductive structure 118B; and a third set including conductive element 106C, second dielectric element 108C, and second conductive structure 118C) are isolated from each other within dielectric structure 103. Accordingly, in some embodiments, each set of elements may constitute a separate transistor of the flash memory structure, with the separate transistors further including a common blocking dielectric (e.g., first dielectric element 116), channel (e.g., semiconductor structure 110), source (e.g., conductive layer 102), and drain (e.g., first conductive structure 104). Such a structure may be useful when the memory cell represented by the three transistors are configured to be programmed, erased, and/or read at different times.

In some embodiments, the lateral lengths of conductive elements 106A, 106B, and 106C may vary such that each successive conductive element, from lowest to highest in position, may be laterally shorter than a previous conductive element. Consequently, in FIG. 2B, conductive element 106A may be the longest, conductive element 106C may be the shortest, and conductive element 106B may have an intermediate lateral length. In some embodiments, arranging conductive elements 106A, 106B, and 106C in such a manner may facilitate access to each conductive element 106A, 106B, and 106C from above. Consequently, corresponding pairs of dielectric elements and conductive structures (e.g., second dielectric element 108A and second conductive structure 118A; conductive element 106B and second dielectric element 108B and second conductive structure 118B; second dielectric element 108C and second conductive structure 118C) may also proceed from deepest to shallowest in depth from left to right for compatibility with the depth of conductive elements 106A, 106B, and 106C within IC device 200B.

While three sets of elements representing three transistors are illustrated in FIG. 2B, other embodiments may include two or more sets of such elements to create a corresponding number of transistors employing a single source and drain configuration.

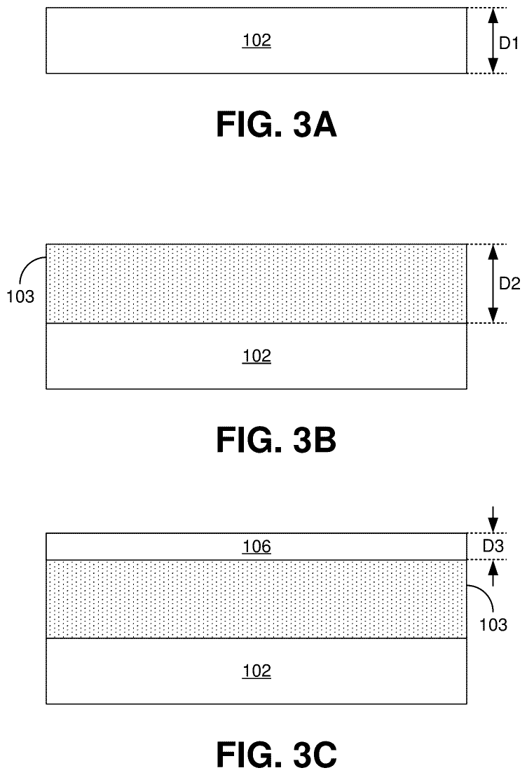

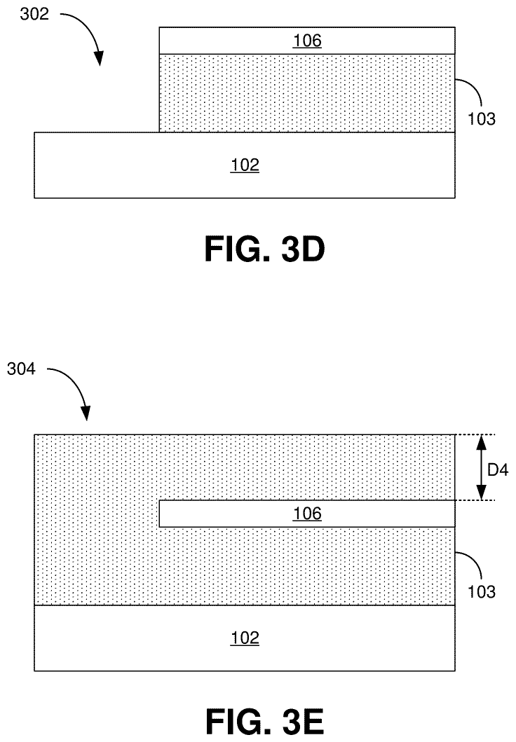

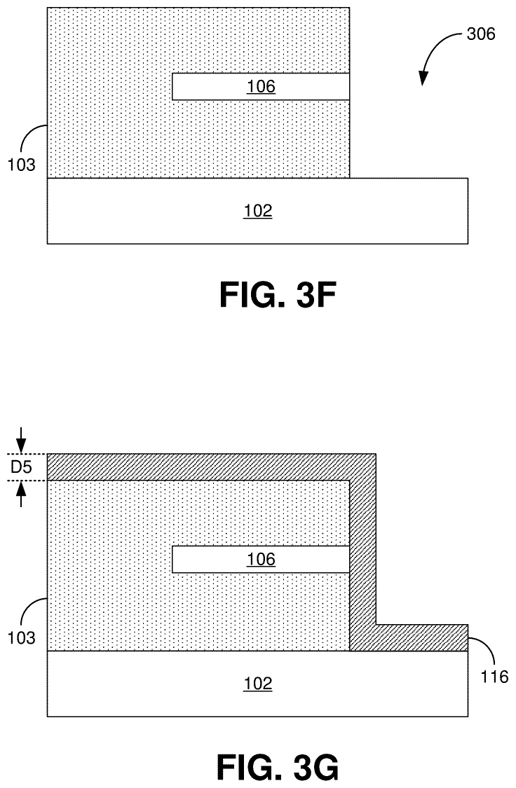

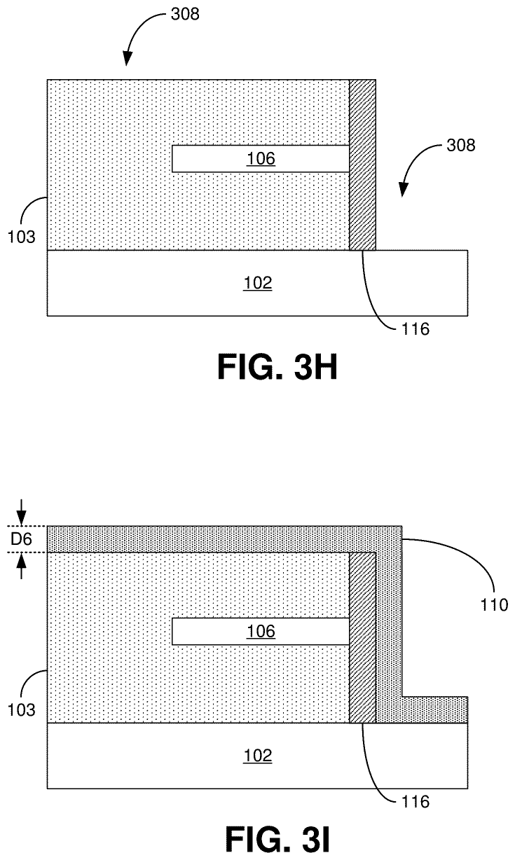

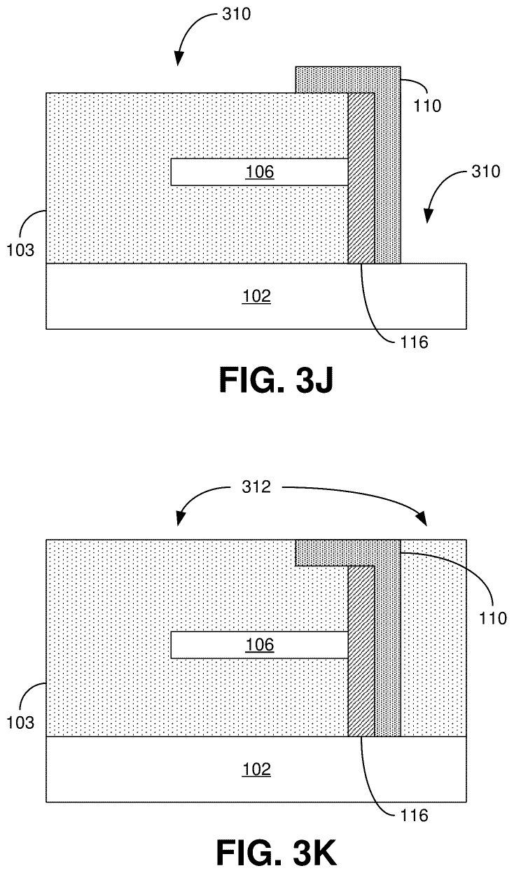

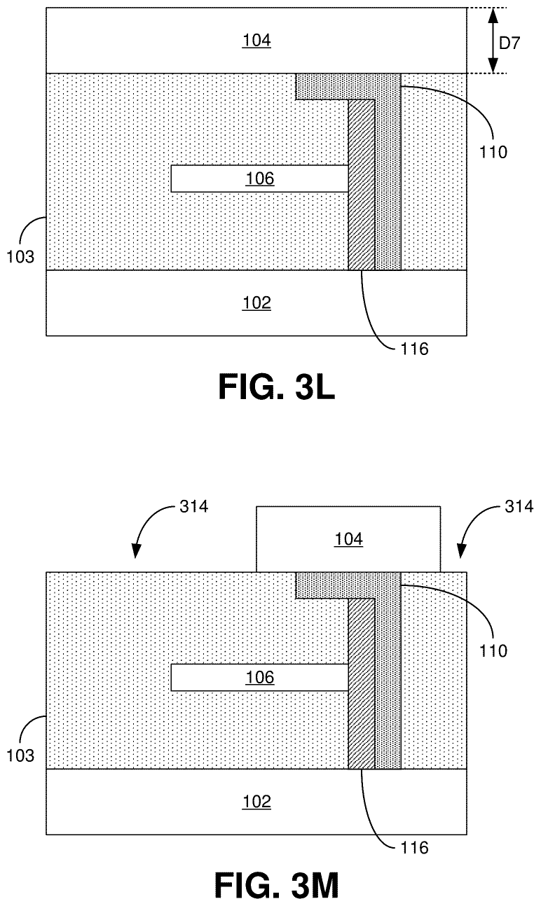

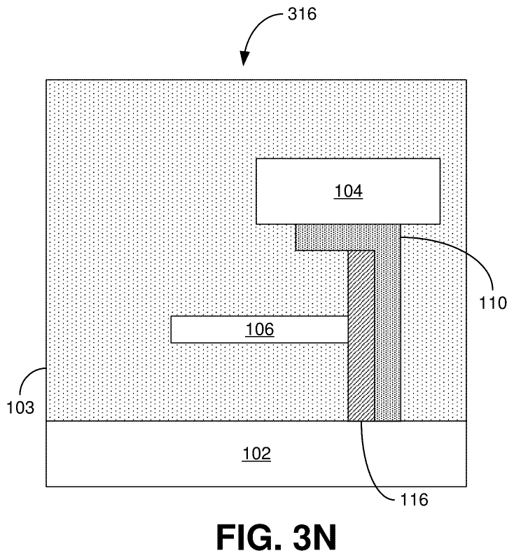

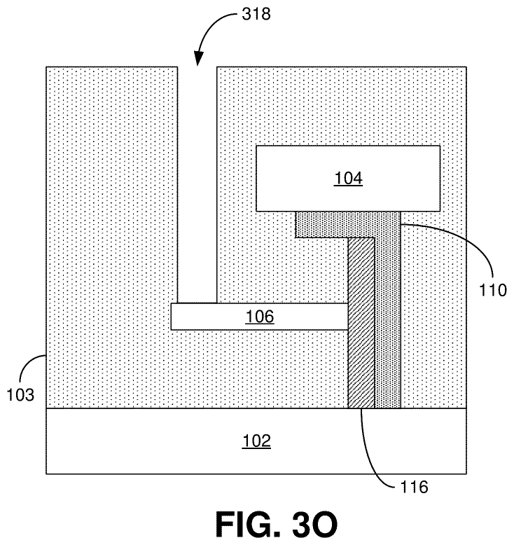

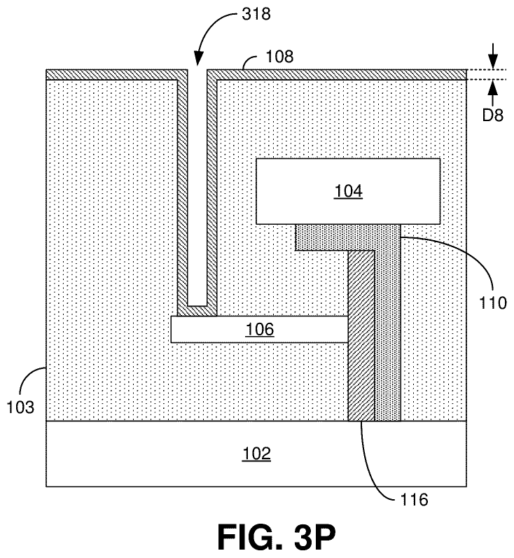

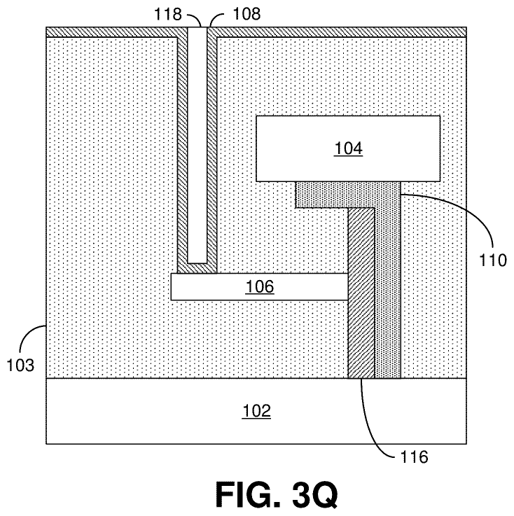

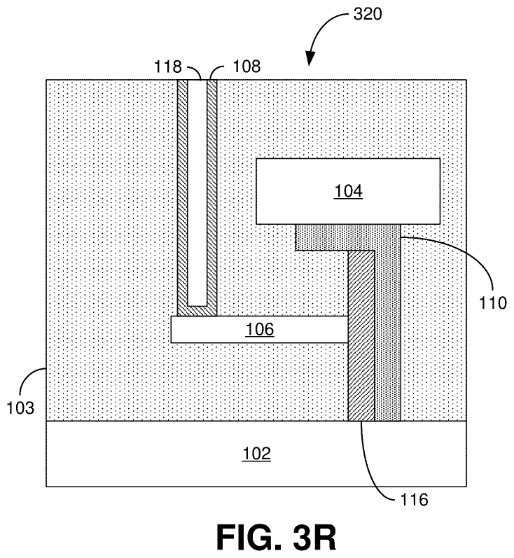

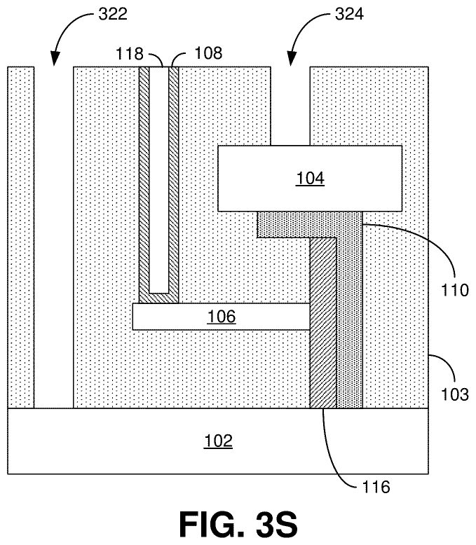

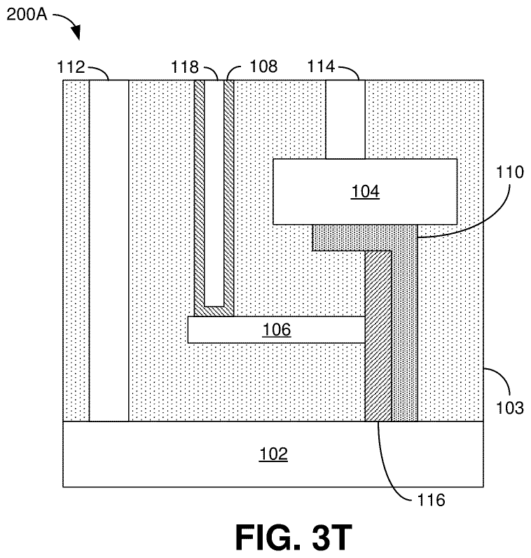

FIGS. 3A through 3T illustrate cross-sectional views of some embodiments of an IC device 200A of FIG. 2A that includes a single-transistor 3D inverted flash memory structure at multiple stages of fabrication, according to the present disclosure. Although FIGS. 3A through 3T are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 3A illustrates a conductive layer 102 that may serve as a substrate, or as a layer disposed over a substrate, for the remaining structural elements of IC device 200A. In some embodiments, conductive layer 102 may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy. Further, in some embodiments, a thickness D1 of conductive layer 102 may be in the range of 1 nanometer to 20 nanometers.

FIG. 3B illustrates the forming (e.g., deposition) of a dielectric material that ultimately is included in dielectric structure 103 on conductive layer 102. In some embodiments, the dielectric material may include silicon oxide (SiOₓ), such as silicon dioxide (SiO₂), or another oxide or dielectric material. Further, in some embodiments, this portion of dielectric structure 103 may have a thickness D2 in the range of 1 nanometer to 10 nanometers.

FIG. 3C illustrates the forming (e.g., deposition) of a conductive layer on the first dielectric material of dielectric structure 103 that ultimately becomes conductive element 106. In some embodiments, this conductive layer may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy. Further, in some embodiments, a thickness D3 of this conductive layer may be in the range of 1 nanometer to 20 nanometers.

FIG. 3D illustrates the removal (e.g., photolithography and associated etching 302) of conductive element 106 and dielectric structure 103 to expose a portion of conductive layer 102. In some embodiments, such removal results in the defining of the second end of conductive element 106, mentioned above.

FIG. 3E illustrates the forming (e.g., deposition) of additional dielectric material 304 to dielectric structure 103. In some embodiments, such dielectric material 304 may be the same as that mentioned above with respect to FIG. 3B (e.g., silicon oxide (SiOₓ), such as silicon dioxide (SiO₂), or another oxide or dielectric material). In some embodiments, the additional dielectric material 304 may have a thickness D4 in the range of 1 nanometer to 10 nanometers.

FIG. 3F illustrates the removal (e.g., photolithography and associated etching 306) of dielectric structure 103 and conductive element 106 to expose another portion of conductive layer 102. In some embodiments, such removal, as discussed hereafter, may provide the surface upon which first dielectric element 116 and semiconductor structure 110 are formed. Also, in some embodiments, the removal may define the first end of conductive element 106 opposite the second end of conductive element 106, and thus configure the lateral extent of conductive element 106.

For example, FIG. 3G illustrates the forming (e.g., conformal deposition) of a first dielectric layer that ultimately forms first dielectric element 116. In some embodiments, such forming may result in the dielectric material covering dielectric structure 103, the first end of conductive element 106, and the exposed portion of conductive layer 102. Also, in some embodiments, first dielectric element 116 (e.g., operating as a block oxide) may include silicon nitride (SiN), silicon dioxide (SiO₂), hafnium oxide (HfO₂), zirconium dioxide (ZrO₂), hafnium zirconium oxide (HfZrO), aluminum oxide (Al₂O₃), titanium dioxide (TiO₂), magnesium oxide (MgO), lanthanum oxide (La₂O₃), niobium suboxide (NbOₓ), or multiple layers selected therefrom (e.g., HfO₂/Al₂O₃). Further, in some embodiments, a thickness D5 of first dielectric element 116 may be in the range of 5 nanometers to 20 nanometers.

FIG. 3H illustrates the removal (e.g., etching 308, such as blanket etching or “spacer-like” etching 308) of lateral portions of the first dielectric layer to form first dielectric element 116. In some embodiments, such removal results in leaving the vertically-oriented portion of the first dielectric layer along a side of dielectric structure 103 and the first end of conductive element 106 to provide first dielectric element 116.

FIG. 3I illustrates the forming (e.g., conformal deposition) of a semiconductor layer that ultimately forms semiconductor structure 110. In some embodiments, the semiconductor layer may cover dielectric structure 103, first dielectric element 116, and the exposed portion of conductive layer 102. In some embodiments, the semiconductor layer may include silicon (Si), germanium (Ge), silicon-germanium (SiGe), indium gallium zinc oxide (IGZO), indium oxide (InOₓ), indium zinc oxide (IZO), indium tin oxide (ITO), stannous oxylate (SnOₓ), nickel oxide (NiO), cuprous oxide (Cu₂O), or combinations thereof. Further, in some embodiments, the semiconductor layer may have a thickness D6 in the range of 1 nanometer to 20 nanometers.

FIG. 3J illustrates removal (e.g., lithography and associated etching 310) of sections of laterally-directed portions of the semiconductor layer to form semiconductor structure 110. In some embodiments, semiconductor structure 110 includes a portion that extends vertically from conductive layer 102 and alongside and over first dielectric element 116. Further, in some embodiments, semiconductor structure 110 may also extend laterally over a portion of dielectric structure 103.

FIG. 3K illustrates the forming (e.g., deposition 312) of additional dielectric material for dielectric structure 103. As indicated above, such additional dielectric material may include silicon oxide (SiOₓ), such as silicon dioxide (SiO₂), or another oxide or dielectric material. In some embodiments, an upper surface of dielectric structure 103 substantially matches an upper surface of semiconductor structure 110. Further, in some embodiments, an upper surface of dielectric structure 103 and semiconductor structure 110 may also be planarized (e.g., using chemical-mechanical planarization (CMP)).

FIG. 3L illustrates the forming (e.g., deposition) of a conductive layer on dielectric structure 103 and semiconductor structure 110 to create first conductive structure 104. In some embodiments, first conductive structure 104 may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy. Further, in some embodiments, a thickness D7 of this conductive layer may be in the range of 1 nanometer to 20 nanometers.

FIG. 3M illustrates the removal (e.g., lithography and associated etching 314) of one or more portions of the conductive layer formed in FIG. 3L to create first conductive structure 104. In some embodiments, first conductive structure 104 may laterally extend beyond either end of an upper surface of semiconductor structure 110.

FIG. 3N illustrates the forming (e.g., deposition 316) of additional dielectric material for dielectric structure 103. In some embodiments, this additional dielectric material may be the same as lower portions of dielectric structure 103, and may include silicon oxide (SiOₓ), such as silicon dioxide (SiO₂), or another oxide or dielectric material.

FIG. 3O illustrates the forming (e.g., lithography and associated etching) of a trench 318 into dielectric structure 103, which may extend to conductive element 106.

FIG. 3P illustrates the forming (e.g., conformal deposition) of a second dielectric layer that ultimately becomes second dielectric element 108. In some embodiments, the second dielectric layer covers the upper surface of dielectric structure 103, as well as the sidewalls and bottom of trench 318. Also, in some embodiments, the second dielectric layer (e.g., operating as a tunnel oxide) may include silicon nitride (SiN), silicon dioxide (SiO₂), hafnium oxide (HfO₂), zirconium dioxide (ZrO₂), hafnium zirconium oxide (HfZrO), aluminum oxide (Al₂O₃), titanium dioxide (TiO₂), magnesium oxide (MgO), lanthanum oxide (La₂O₃), niobium suboxide (NbOₓ), or multiple layers selected therefrom (e.g., HfO₂/Al₂O₃). Further, in some embodiments, a thickness D8 of first dielectric element 116 may be in the range of 5 nanometers to 10 nanometers.

FIG. 3Q illustrates the forming (e.g., filling) of conductive material in trench 318 to form second conductive structure 118. As indicated above, the conductive material may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy.

FIG. 3R illustrates the planarizing (e.g., blanket etching 320 and/or planarization) of an upper surface of the second dielectric layer and the conductive material to form second conductive structure 118 and second dielectric element 108 surrounding second conductive structure 118 in trench 318.

FIG. 3S illustrates the forming of a first contact trench 322 into dielectric structure 103 and extending to conductive layer 102, as well as the forming of a second contact trench 324 into dielectric structure 103 and extending to first conductive structure 104.

FIG. 3T illustrates the forming (e.g., filling) of conductive material into first contact trench 322 and second contact trench 324 to form a first conductive contact structure 112 and a second conductive contact structure 114, respectively, to produce IC device 200A. Similar to the conductive structures discussed above, first conductive contact structure 112 and second conductive contact structure 114 may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy. In addition, planarizing of the resulting upper surface of IC device 200A (e.g., using CMP) may also be performed (e.g., in anticipation of other circuitry to be fabricated thereon, such as other flash memory structures, programming and/or erasing control circuitry, read and/or write control circuitry, and so on).

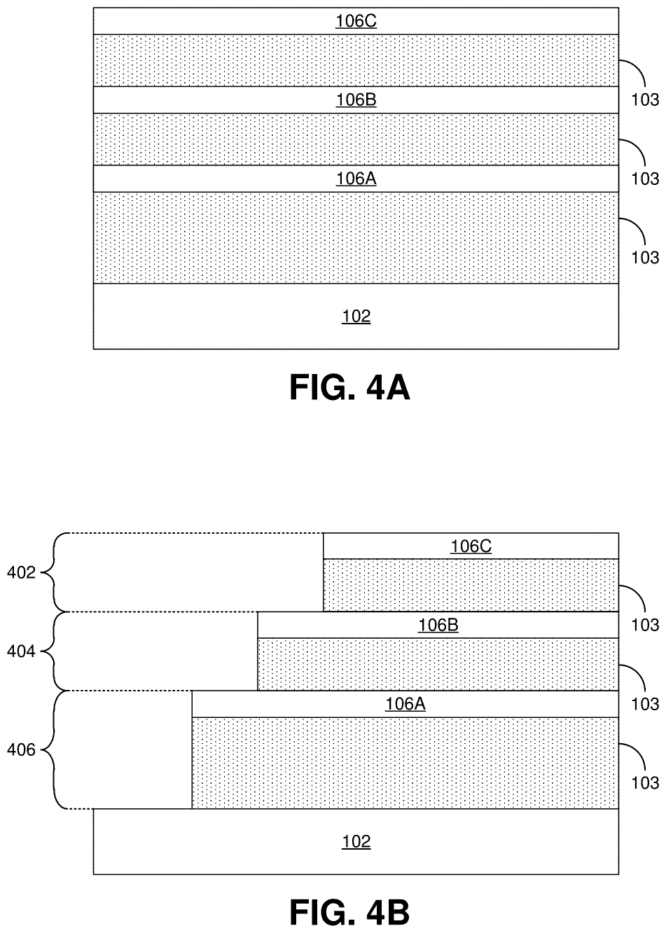

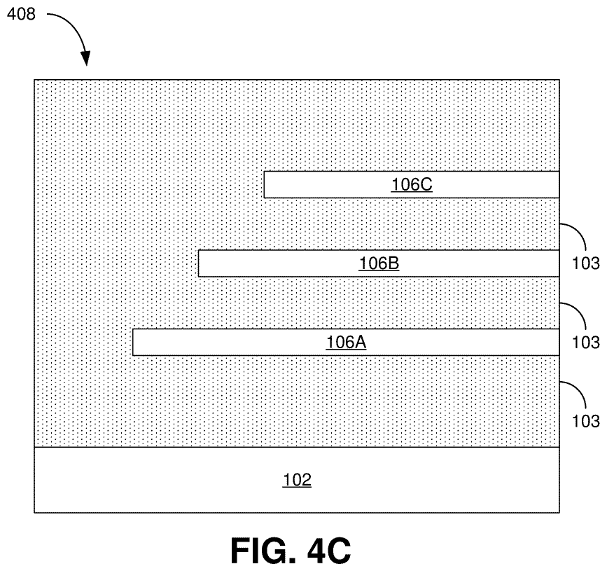

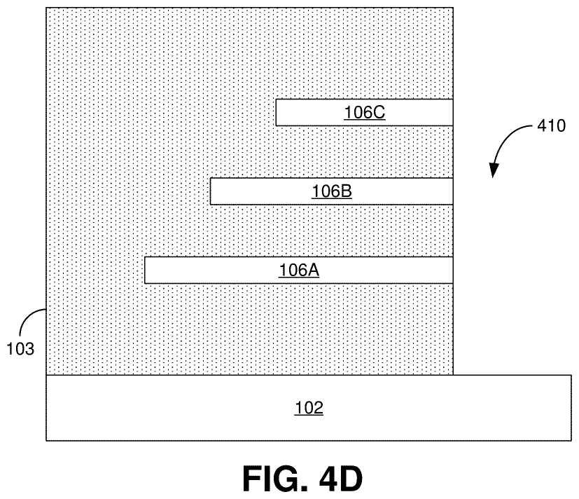

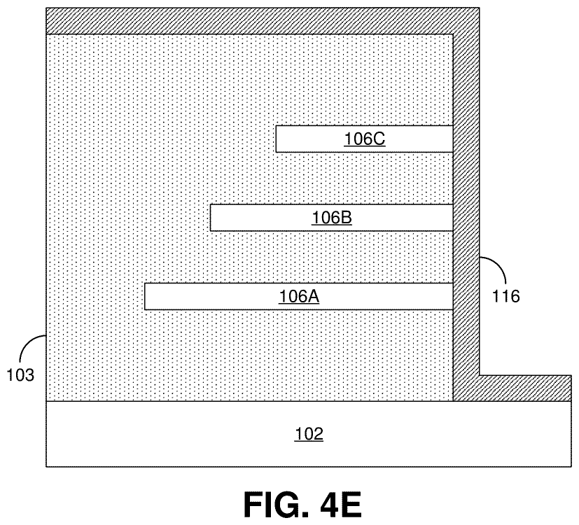

While FIGS. 3A through 3T illustrate IC device 200A of FIG. 2A that includes a single-transistor 3D inverted flash memory structure at multiple stages of fabrication, at least some such stages may be applied the fabrication of IC device 200B of FIG. 2B directed to a multiple-transistor 3D inverted flash memory structure in some embodiments. To that end, FIGS. 4A through 4E illustrate cross-sectional views of some embodiments of IC device 200B including a multiple-transistor 3D inverted flash memory structure at early multiple stages of fabrication, according to the present disclosure.

FIG. 4A, for example, illustrates the forming (e.g., deposition) of several layers of conductive and dielectric material over conductive layer 102 to provide a basis for multiple (e.g., three) conductive elements 106A, 106B, and 106C, in a manner similar to the single-transistor case of FIGS. 3A through 3C. More specifically, in some embodiments, over conductive layer 102 may be deposited, in order, a first dielectric material, a first conductive material, a second dielectric material, a second conductive material, a third dielectric material, and a third conductive material to ultimately form conductive elements 106A, 106B, and 106C within dielectric structure 103. As described above, first, second, and third dielectric material may include silicon oxide (SiOₓ), such as silicon dioxide (SiO₂), or another oxide or dielectric material. Also, first, second, and third conductive materials may include one or more of titanium nitride (TiN), titanium (Ti), tungsten (W), molybdenum (Mo), niobium (Nb), tantalum nitride (TaN), ruthenium (Ru), aluminum (Al), titanium aluminide (TiAl), palladium (Pd), platinum (Pt), nickel (Ni), polycrystalline silicon (poly-Si), or another metal or alloy. In some embodiments, a thickness of conductive layer 102 may be the same thickness D1 as discussed above in connection with FIG. 3A. Also, in some embodiments, a thickness of dielectric structure 103 between conductive layer 102 and conductive element 106A may be similar to thickness D2, as described above in conjunction with FIG. 3B. Further, in some embodiments, a thickness of each of conductive elements 106A, 106B, and 106C may be similar to thickness D3 of conductive element 106 of FIG. 3C.

FIG. 4B illustrates the removal (e.g., lithography and associated etching) of dielectric structure 103 and conductive elements 106A, 106B, and 106C (e.g., in a staged, stepped, or staircase manner) corresponding to the fabrication stage of FIG. 3D. More specifically, in some embodiments, a first etching 402 may remove a portion of third conductive element 106C and underlying dielectric material, extending downward to second conductive element 106B. A second etching 404 may remove a smaller portion of second conductive element 106B and underlying dielectric material, extending downward to first conductive element 106A. Thereafter, a third etching 406 may remove an even smaller portion of first conductive element 106A and underlying dielectric material, extending downward to conductive layer 102. Such etching, in some embodiments, may define the second end of each of conductive elements 106A, 106B, and 106C. For example, progressing upward from conductive layer 102, a lateral extent or length of each proceeding conductive element 106A, 106B, and 106C may become smaller (e.g., to allow a vertical path upward through dielectric structure 103 to place second conductive structures 118A, 118B, and 118C, and associated second dielectric elements 108A, 108B, and 108C, as depicted in FIG. 2B).

FIG. 4C illustrates the forming (e.g., filling 408) of additional dielectric material for dielectric structure 103, in a manner corresponding to the stage depicted in FIG. 3E. In some embodiments, the thickness of the additional dielectric material may be similar to thickness D4 illustrated in FIG. 3E.

FIG. 4D illustrates the removal (etching 410) of dielectric structure 103 and conductive elements 106A, 106B, and 106C to expose a portion of conductive layer 102, in a manner corresponding to that of FIG. 3F. Further, in some embodiments, as such etching may define the first end of conductive elements 106A, 106B, and 106C.

FIG. 4E illustrates the forming (e.g., conformal deposition) of a first dielectric layer over dielectric structure 103, the first end of conductive elements 106A, 106B, and 106C, and the exposed portion of conductive layer 102 to ultimately form first dielectric element 116 in a manner corresponding to that of FIG. 3G. In some embodiments, a thickness of the first dielectric layer may be similar to thickness D5 depicted in FIG. 3G.

Thereafter, additional fabrication stages after FIG. 4E for IC device 200B of FIG. 2B may substantially follow the processes, materials, dimensions, etc., according to FIGS. 3H through 3T associated with the fabrication of IC device 200A of FIG. 2A. More specifically, each of the operations associated with FIGS. 3H through 3T that apply to conductive element 106, second dielectric element 108, and second conductive structure 118 of IC device 200A may be applied in a corresponding manner to conductive elements 106A, 106B, and 106C, second dielectric elements 108A, 108B, and 108C, and second conductive structures 118A, 118B, and 118C of IC device 200B.

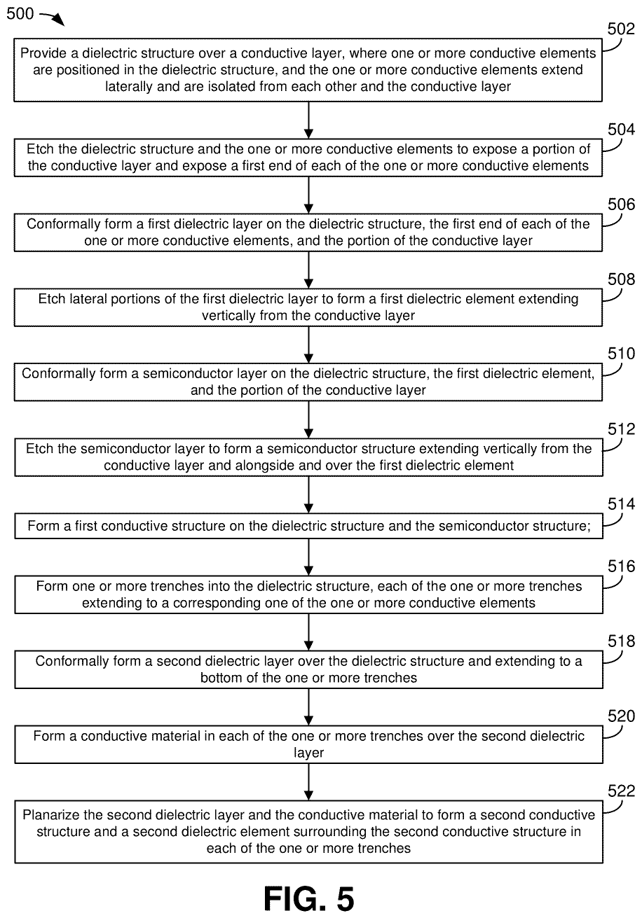

FIG. 5 illustrates a methodology 500 of forming some embodiments of the IC device 200A of the single-transistor 3D inverted flash memory structure of FIGS. 3A through 3T and the IC device 200B of the multiple-transistor 3D inverted flash memory structure of FIGS. 4A through 4E, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 502, for example, a dielectric structure (e.g., dielectric structure 103) is provided over a conductive layer (e.g., conductive layer 102), where one or more conductive elements (e.g., conductive element 106 or conductive elements 106A, 106B, and 106C) are positioned in the dielectric structure, and the one or more conductive elements extend laterally and are isolated from each other and the conductive layer. FIGS. 3A through 3E and FIGS. 4A through 4C illustrate cross-sectional views of some embodiments corresponding to Act 502.

At Act 504, the dielectric structure and the one or more conductive elements are etched to expose a portion of the conductive layer and expose a first end of each of the one or more conductive elements. FIG. 3F and FIG. 4D illustrate cross-sectional views of some embodiments corresponding to Act 504.

At Act 506, a first dielectric layer (e.g., associated with first dielectric element 116) is conformally formed on the dielectric structure, the first end of each of the one or more conductive elements, and the portion of the conductive layer. FIG. 3G and FIG. 4E illustrate cross-sectional views of some embodiments corresponding to Act 506.

At Act 508, lateral portions of the first dielectric layer are etched to form a first dielectric element (e.g., first dielectric element 116) extending vertically from the conductive layer. FIG. 3H illustrates a cross-sectional view of some embodiments corresponding to Act 508.

At Act 510, a semiconductor layer (e.g., associated with semiconductor structure 110) is conformally formed on the dielectric structure, the first dielectric element, and the portion of the conductive layer. FIG. 3I illustrates a cross-sectional view of some embodiments corresponding to Act 510.

At Act 512, the semiconductor layer is etched to form a semiconductor structure (e.g., semiconductor structure 110) extending vertically from the conductive layer and alongside and over the first dielectric element. FIG. 3J illustrates a cross-sectional view of some embodiments corresponding to Act 512.

At Act 514, a first conductive structure (e.g., first conductive structure 104) is formed on the dielectric structure and the semiconductor structure. FIGS. 3K and 3L illustrate cross- sectional views of some embodiments corresponding to Act 514.

At Act 516, one or more trenches (e.g., trench 318) are formed into the dielectric structure, each of the one or more trenches extending to a corresponding one of the one or more conductive elements. FIG. 3O illustrates a cross-sectional view of some embodiments corresponding to Act 516.

At Act 518, a second dielectric layer (e.g., associated with second dielectric element 108) is conformally formed over the dielectric structure and extending to a bottom of the one or more trenches. FIG. 3P illustrates a cross-sectional view of some embodiments corresponding to Act 518.

At Act 520, a conductive material (e.g., associated with second conductive structure 118) is formed in each of the one or more trenches over the second dielectric layer. FIG. 3Q illustrates a cross-sectional view of some embodiments corresponding to Act 520.

At Act 522, the second dielectric layer and the conductive material are planarized to form a second conductive structure (e.g., second conductive structure 118) and a second dielectric element (e.g., second dielectric element 108) surrounding the second conductive structure in each of the one or more trenches. FIG. 3R illustrates a cross-sectional view of some embodiments corresponding to Act 522.

Some embodiments relate to an integrated circuit (IC) device. The device includes: a conductive layer; a dielectric structure disposed over the conductive layer; a first conductive structure disposed within the dielectric structure and separated from the conductive layer; a semiconductor structure disposed within the dielectric structure and extending vertically from the conductive layer to the first conductive structure; a first dielectric element disposed within the dielectric structure and extending vertically from the conductive layer alongside the semiconductor structure; a conductive element disposed within the dielectric structure between and separated from the conductive layer and the first conductive structure, and extending laterally from the first dielectric element; a second conductive structure disposed within the dielectric structure and extending vertically from near a surface of the conductive element opposite the conductive layer; and a second dielectric element disposed within the dielectric structure and at least partially surrounding the second conductive structure to isolate the second conductive structure from the conductive element and the dielectric structure.

Some embodiments relate to another IC device. The device includes: a conductive layer; a dielectric structure disposed over the conductive layer; a first conductive structure disposed within the dielectric structure and separated from the conductive layer; a semiconductor structure disposed within the dielectric structure and extending vertically from the conductive layer to the first conductive structure; a first dielectric element disposed within the dielectric structure and extending vertically from the conductive layer alongside the semiconductor structure; a plurality of conductive elements disposed within the dielectric structure between and separated from the conductive layer and the first conductive structure, vertically separated from each other, and extending laterally from the first dielectric element; a plurality of second conductive structures disposed within the dielectric structure, each of the plurality of second conductive structures extending vertically from near a surface of a corresponding one of the plurality of conductive elements opposite the conductive layer; and a plurality of second dielectric elements disposed within the dielectric structure, each of the plurality of second dielectric elements at least partially surrounding a corresponding one of the plurality of second conductive structures to isolate the corresponding one of the plurality of second conductive structures from a corresponding one of the plurality of conductive elements and the dielectric structure.

Some embodiments relate to a method. The method includes: providing a dielectric structure over a conductive layer, wherein one or more conductive elements are positioned in the dielectric structure, and the one or more conductive elements extend laterally and are isolated from each other and the conductive layer; etching the dielectric structure and the one or more conductive elements to expose a portion of the conductive layer and expose a first end of each of the one or more conductive elements; conformally forming a first dielectric layer on the dielectric structure, the first end of each of the one or more conductive elements, and the portion of the conductive layer; etching lateral portions of the first dielectric layer to form a first dielectric element extending vertically from the conductive layer; conformally forming a semiconductor layer on the dielectric structure, the first dielectric element, and the portion of the conductive layer; etching the semiconductor layer to form a semiconductor structure extending vertically from the conductive layer and alongside and over the first dielectric element; forming a first conductive structure on the dielectric structure and the semiconductor structure; forming one or more trenches into the dielectric structure, each of the one or more trenches extending to a corresponding one of the one or more conductive elements; conformally forming a second dielectric layer over the dielectric structure and extending to a bottom of the one or more trenches; forming a conductive material in each of the one or more trenches over the second dielectric layer; and planarizing the second dielectric layer and the conductive material to form a second conductive structure and a second dielectric element surrounding the second conductive structure in each of the one or more trenches.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a conductive layer;
a dielectric structure disposed over the conductive layer;
a first conductive structure disposed within the dielectric structure and separated from the conductive layer;
a semiconductor structure disposed within the dielectric structure and extending vertically from the conductive layer to the first conductive structure;
a first dielectric element disposed within the dielectric structure and extending vertically from the conductive layer alongside the semiconductor structure;
a conductive element disposed within the dielectric structure between and separated from the conductive layer and the first conductive structure, and extending laterally from the first dielectric element;
a second conductive structure disposed within the dielectric structure and extending vertically from near a surface of the conductive element opposite the conductive layer; and
a second dielectric element disposed within the dielectric structure and at least partially surrounding the second conductive structure to isolate the second conductive structure from the conductive element and the dielectric structure.

2. The IC device of claim 1, further comprising:
a first conductive contact structure disposed within the dielectric structure and extending vertically from the conductive layer; and
a second conductive contact structure disposed within the dielectric structure and extending vertically from the first conductive structure away from the conductive layer.

3. The IC device of claim 2, wherein the second conductive structure is disposed laterally between the first conductive contact structure and the second conductive contact structure.

4. The IC device of claim 1, wherein a portion of the semiconductor structure further extends laterally along a surface of the first conductive structure facing the conductive layer and isolates the first conductive structure from the first dielectric element.

5. The IC device of claim 4, wherein a vertical distance between the portion of the semiconductor structure and the conductive element is in a range of 1 to 10 nanometers.

6. The IC device of claim 1, wherein a vertical distance between the conductive element and the conductive layer is in a range of 1 to 10 nanometers.

7. An integrated circuit (IC) device, comprising:
a conductive layer;
a dielectric structure disposed over the conductive layer;
a first conductive structure disposed within the dielectric structure and separated from the conductive layer;
a semiconductor structure disposed within the dielectric structure and extending vertically from the conductive layer to the first conductive structure;
a first dielectric element disposed within the dielectric structure and extending vertically from the conductive layer alongside the semiconductor structure;
a plurality of conductive elements disposed within the dielectric structure between and separated from the conductive layer and the first conductive structure, vertically separated from each other, and extending laterally from the first dielectric element;
a plurality of second conductive structures disposed within the dielectric structure, each of the plurality of second conductive structures extending vertically from near a surface of a corresponding one of the plurality of conductive elements opposite the conductive layer; and
a plurality of second dielectric elements disposed within the dielectric structure, each of the plurality of second dielectric elements at least partially surrounding a corresponding one of the plurality of second conductive structures to isolate the corresponding one of the plurality of second conductive structures from a corresponding one of the plurality of conductive elements and the dielectric structure.

8. The IC device of claim 7, further comprising:
a first conductive contact structure disposed within the dielectric structure and extending vertically from the conductive layer; and
a second conductive contact structure disposed within the dielectric structure and extending vertically from the first conductive structure away from the conductive layer.

9. The IC device of claim 8, wherein each of the plurality of second conductive structures is disposed laterally between the first conductive contact structure and the second conductive contact structure.

10. The IC device of claim 7, wherein, when progressing from a first one of the plurality of conductive elements nearest the conductive layer, each of a second one of the plurality of conductive elements through a last one of the plurality of conductive elements is laterally shorter than an immediately previous one of the plurality of conductive elements.

11. The IC device of claim 7, wherein a portion of the semiconductor structure further extends laterally along a surface of the first conductive structure facing the conductive layer and isolates the first conductive structure from the first dielectric element.

12. A method, comprising:
providing a dielectric structure over a conductive layer, wherein one or more conductive elements are positioned in the dielectric structure, and the one or more conductive elements extend laterally and are isolated from each other and the conductive layer;
etching the dielectric structure and the one or more conductive elements to expose a portion of the conductive layer and expose a first end of each of the one or more conductive elements;
conformally forming a first dielectric layer on the dielectric structure, the first end of each of the one or more conductive elements, and the portion of the conductive layer;
etching lateral portions of the first dielectric layer to form a first dielectric element extending vertically from the conductive layer;
conformally forming a semiconductor layer on the dielectric structure, the first dielectric element, and the portion of the conductive layer;
etching the semiconductor layer to form a semiconductor structure extending vertically from the conductive layer and alongside and over the first dielectric element;
forming a first conductive structure on the dielectric structure and the semiconductor structure;
forming one or more trenches into the dielectric structure, each of the one or more trenches extending to a corresponding one of the one or more conductive elements;
conformally forming a second dielectric layer over the dielectric structure and extending to a bottom of the one or more trenches;
forming a conductive material in each of the one or more trenches over the second dielectric layer; and
planarizing the second dielectric layer and the conductive material to form a second conductive structure and a second dielectric element surrounding the second conductive structure in each of the one or more trenches.

13. The method of claim 12, further comprising:
forming, prior to forming the one or more trenches, additional dielectric material on the dielectric structure;
forming a first contact trench into the dielectric structure, extending to the conductive layer;
forming a second contact trench into the dielectric structure, extending to the first conductive structure;
filling the conductive material in the first contact trench to form a first conductive contact structure; and
filling the conductive material in the second contact trench to form a second conductive contact structure.

14. The method of claim 13, wherein the one or more trenches are positioned between the first contact trench and the second contact trench.

15. The method of claim 12, wherein each of the one or more trenches extends proximate a second end opposite the first end of a corresponding one of the one or more conductive elements.

16. The method of claim 12, wherein when the one or more conductive elements comprises at least two conductive elements, a lateral length of each of the one or more conductive elements is less than the lateral length of any remaining ones of the one or more conductive elements closer to the conductive layer.

17. The method of claim 12, wherein the semiconductor layer comprises two or more layers of different semiconductor materials.

18. The method of claim 12, wherein a thickness of the semiconductor layer is in a range from 1 nanometer to 20 nanometers.

19. The method of claim 12, wherein a thickness of the first dielectric layer is in a range from 5 nanometers to 20 nanometers.

20. The method of claim 12, wherein:
a thickness of each of the one or more conductive elements is in a range from 1 nanometer to 20 nanometers; and
a thickness of the second dielectric layer is in a range from 5 nanometers to 10 nanometers.
